(19) United States
(12) Patent Application Publication
(10) Pub. No.: US 2026/0209501 A1
(43) Pub. Date: Jul. 23, 2026

(54) COMPOSITION, SHEET, AND METAL-CLAD LAMINATE

(71) Applicant: DAIKIN INDUSTRIES, LTD., Osaka (JP)

(72) Inventors: Moe HOSOKAWA, Osaka (JP); Shingo OKUNO, Osaka (JP); Kyohei SAWAKI, Osaka (JP); Yoshito TANAKA, Osaka (JP); Akiyoshi YAMAUCHI, Osaka (JP); Yosuke KISHIKAWA, Osaka (JP)

(73) Assignee: DAIKIN INDUSTRIES, LTD., Osaka (JP)

(21) Appl. No.: 19/571,934

(22) Filed: Mar. 19, 2026

Related U.S. Application Data
(63) Continuation of application No. PCT/JP2024/033908, filed on Sep. 24, 2024.

(30) Foreign Application Priority Data
Sep. 25, 2023 (JP) 2023-160431

(51) Int. Cl. C08L 27/18; B32B 15/085; B32B 15/20; B32B 27/32; C08J 5/18; C08K 9/10

(52) U.S. Cl. CPC C08L 27/18; B32B 15/085; B32B 15/20; B32B 27/322; C08J 5/18; C08K 9/10; B32B 2250/02; B32B 2327/18; B32B 2457/08; C08J 2327/18; C08K 2201/005

(57) ABSTRACT

A composition that suppresses water absorption and moisture absorption, particularly a composition for providing a sheet with suppressed increase in dielectric loss tangent due to moisture absorption, and a sheet and metal-clad laminate using the same. A composition including a fluororesin, an inorganic particle, and an organosiloxane. A sheet and a metal-clad laminate using the composition.

### CROSS-REFERENCE TO RELATED APPLICATIONS

This application is a Rule 53(b) Continuation of International Application No. PCT/JP2024/033908 filed Sep. 24, 2024, which claims priority based on Japanese Patent Application No. 2023-160431 filed Sep. 25, 2023, the respective disclosures of which are incorporated herein by reference in their entirety.

### TECHNICAL FIELD

The present disclosure relates to a composition, a sheet, and a metal-clad laminate.

### BACKGROUND ART

In high-frequency printed wiring boards, those with a low transmission loss have been demanded. It is well known to use a fluororesin film in such high-frequency printed wiring boards (Patent Literature 1 and the like) Patent Literatures 2 and 3 disclose the use of a fluororesin compounded with a filler as a wiring board material.

Patent Literature 4 discloses the use of a fluororesin composition for a circuit board, in which perfect spherical silica particles are compounded therein.

Patent Literature 5 discloses forming a polymer layer on a substrate using a dispersion containing a tetrafluoroethylene-based polymer and a liquid compound having a specific kinematic viscosity and boiling point, to obtain a laminate.

### CITATION LIST

### Patent Literature

Patent Literature 1: Japanese Patent Laid-Open No. 2015-8260
Patent Literature 2: Japanese Patent Laid-Open No. 63-259907
Patent Literature 3: Japanese Translation of PCT International Application Publication No. 2022-510017
Patent Literature 4: International Publication No. WO 2020/145133
Patent Literature 5: Japanese Patent Laid-Open No. 2022-69962

### SUMMARY

The present disclosure is a composition containing a fluororesin, an inorganic particle, and an organosiloxane.

The inorganic particle is preferably inorganic particle containing silica as an essential component.

The fluororesin is preferably a perfluorinated fluororesin.

The perfluorinated fluororesin is preferably polytetrafluoroethylene (PTFE).

### DESCRIPTION OF EMBODIMENTS

The present disclosure will be described in detail below.

Compositions in which fluororesins and other resins are compounded with fillers such as inorganic particles have extensively been investigated.

However, for example, sheets to be used in circuit board and the like, which have been produced from compositions containing inorganic particles may suffer from problems such as a poor appearance and a change in properties, particularly an increase in dielectric loss tangent, due to water absorption and moisture absorption attributable to the compounding of inorganic particles.

Also, in other applications, sheets, lenses, and sealants produced from compositions containing inorganic particles may suffer from problems due to moisture absorption attributable to the compounding of inorganic particles, such as changes in light diffusion properties due to dimensional changes for a light diffusion sheet, changes in a refractive index for the lens, and peeling due to dimensional changes for the sealant.

The present disclosure can provide a composition for providing, under highly humid condition, a sheet with suppressed increase in dielectric loss tangent, a light diffusion sheet that has no change in light diffusion properties, a lens that has only a small change in a refractive index, and a sealant that has excellent dimensional stability.

The present disclosure can provide a composition that suppresses water absorption and moisture absorption. In particular, a sheet obtained from the water absorption and moisture absorption suppressing composition containing the fluororesin of the present disclosure exhibits excellent performance such as suppression of poor appearance and a change in properties due to water absorption and suppression of an increase in dielectric loss tangent due to moisture absorption.

The composition disclosed herein is characterized in that a resin is compounded with inorganic particle and an organosiloxane as essential components. The addition of the organosiloxane suppresses water absorption and moisture absorption, providing a composition capable of reducing changes due to water absorption and moisture absorption.

Examples of the shape of a formed article composed of the composition disclosed herein include a sheet shape, a lens shape, and a sealant shape. In addition, the composition of the present disclosure may also be formed into a shape of a laminate partially having a layer composed of the composition.

Furthermore, the composition may also be formed into these shapes from its liquid state through a curing reaction.

The water absorption indicates the degree of adsorption of water molecules clustered by hydrogen bonds, while moisture absorption is an index of the degree of adsorption of water molecules (water vapor). Conventionally, the water absorption has been required to be suppressed, but the moisture absorption has not been particularly referred to. The water absorption has an effect on liquid water, and suppressing the water absorption does not necessarily mean that the effect of water vapor has been suppressed.

The sheet disclosed herein is a sheet that not only has a low rate of water absorption but also low moisture absorption.

Furthermore, the composition disclosed herein is characterized by including a fluororesin, an inorganic particle, and an organosiloxane. That is, the composition disclosed herein is characterized in that a fluororesin is compounded with an organosiloxane together with an inorganic particle.

The mechanism whereby the addition of the organosiloxane suppresses a poor appearance due to water absorption and an increase in dielectric loss tangent due to moisture absorption, has not yet been specifically clarified, but a sheet containing the fluororesin and the inorganic particle is considered to absorb moisture due to water vapor adsorption in voids between the inorganic particle and the fluororesin which is a matrix resin, and it is conjectured that mixing the organosiloxane with a low surface tension together with the fluororesin and inorganic particle to form a composition allows the organosiloxane to spread over the inorganic particle surfaces (void surfaces), and a sheet composed of this composition prevents water vapor from penetrating an inside of the sheet and prevents adsorption of water vapor and clustered water molecules on a sheet surface.

In such a way, the sheet composed of the composition of the present disclosure is less likely to absorb water and moisture, as a result of which its poor appearance and changes in properties, particularly an increase in dielectric loss tangent are considered to be suppressed.

### (Organosiloxane)

The organosiloxane as used in the present disclosure is a compound having a Si—O—Si bond (siloxane bond), in which an organic substituent is bonded to silicon.

The organosiloxane as used in the present disclosure may be an oligomer or a polymer.

A typical example of the organosiloxane includes a compound in which a methyl group is bonded to silicon.

In the present disclosure, dimethylpolysiloxane in which all of its side chain and an end are methyl groups, is preferably used. Among these, linear dimethylpolysiloxane is preferred.

It is to be noted that a volatile organosiloxane is not suitable for the present disclosure. Examples thereof include hexamethyldisiloxane and decamethylcyclopentasiloxane. They volatilize when the sheet is heated to 300° C. or higher, not allowing the effects of the present disclosure to be expected.

Also, in the present disclosure, it is preferable to use a modified organosiloxane in which a methyl group of the dimethylpolysiloxane has been partially modified with a hydrogen atom or various organic groups. The use of modified organosiloxane can be expected to suppress an increase in dielectric loss tangent of the sheet due to moisture absorption, as well as suppress its decomposition upon sintering and the amount of gas generated.

The organosiloxane to be used in the present disclosure is preferably a liquid and has a viscosity preferably from 3 to 18,000 mm²/s (25° C.). The organosiloxane having a viscosity in the range described above is advantageous in that it is easy to be mixed and highly has an effect of suppressing moisture absorption.

The lower limit of the viscosity of the organosiloxane is more preferably 5 mm²/s (25° C.), still more preferably 10 mm²/s (25° C.), and most preferably 20 mm²/s (25° C.). The upper limit of the viscosity of the organosiloxane is more preferably 10,000 mm²/s (25° C.), still more preferably 5,000 mm²/s (25° C.), and most preferably 2,000 mm²/s (25° C.).

In the present disclosure, the viscosity of the organosiloxane is the value measured at 25° C. using an Ubbelohde viscometer.

In addition, in a case in which two or more organosiloxanes are combined for use, the viscosity at 25° C. refers to the viscosity of the mixture.

An example of the above-described modified organosiloxane includes a modified organosiloxane in which a hydrogen atom or an organic group other than a methyl group (hereinafter may be referred to as an organic group or the like) have been introduced into any or all of a side chain, one end, or both ends of the modified organosiloxane. Examples thereof include a modified organosiloxane in which an organic group or the like has been partially introduced into a side chain of the organosiloxane, a modified organosiloxane in which an organic group or the like has been introduced into either one end of the organosiloxane, a modified organosiloxane in which an organic group or the like has been introduced into both ends of the organosiloxane, and a modified organosiloxane in which an organic group or the like has been introduced into a part of the side chain and both ends of the organosiloxane, and may be appropriately selected and used.

Among these, the modified organosiloxane in which an organic group or the like is partially introduced to its side chain is preferable in terms of suppression of the increased rate of the dielectric loss tangent.

It is to be noted that, in the present disclosure, “to have a hydrogen atom at any or all of its side chain, one end, and both ends” means that a single hydrogen atom, rather than a hydrogen atom present within the organic group, is present at any or all of its side chain, one end, and both ends.

Also, the modified organosiloxanes may be either reactive or non-reactive.

It is to be noted that the organosiloxane to be used in the present disclosure does not include a silane coupling agent, which is used to coat an inorganic particle, as described below. Specifically, the organosiloxane to be used in the present disclosure does not include a silane coupling agent having an alkoxy group (—OR (R has from 1 to 6 carbon atoms), a hydroxyl group, or a halogen group such as a chloro group.

Specific examples of the organic group include a carboxyl group, an amino group, an ether group, an epoxy group, a mercapto group, an acrylic group, a methacrylic group, a carbonyl group, a carboxylic acid anhydride group, an alkyl group other than a methyl group, an aralkyl group, a fluoroalkyl group, a perfluoroalkyl group, an aryl group, an ester group, and an amide group, or substituents containing these groups.

Examples of the alkyl group other than a methyl group include alkyl groups having from 1 to 6 carbon atoms, such as ethyl, n-propyl, isopropyl, n-butyl, sec-butyl, isobutyl, tert-butyl, n-pentyl, and n-hexyl groups, with n-butyl, n-pentyl, and n-hexyl groups being preferred.

Examples of the aryl group include aryl groups having from 6 to 10 carbon atoms, such as phenyl and naphthyl groups, with a phenyl group being preferred.

The fluoroalkyl group and perfluoroalkyl group are linear or branched fluoroalkyl groups or perfluoroalkyl groups having from 1 to 50 carbon atoms and may contain an ether bond.

Preferably, they are linear or branched fluoroalkyl groups or perfluoroalkyl groups having from 1 to 40 carbon atoms and may contain an ether bond. More preferably, they are linear or branched fluoroalkyl groups or perfluoroalkyl groups having from 1 to 30 carbon atoms and may contain an ether bond. Particularly preferably, they are linear fluoroalkyl groups or perfluoroalkyl groups having from 1 to 20 carbon atoms and may contain an ether bond.

The modified organosiloxane to be used in the present disclosure preferably has, at any or all of its side chain, one end, and both ends, at least one selected from the group consisting of a hydrogen atom, an amino group, an ether group, an epoxy group, a mercapto group, a carboxyl group, an acrylic group, a methacrylic group, a carboxylic acid anhydride group, an alkyl group other than a methyl group, an aralkyl group, a fluoroalkyl group, a perfluoroalkyl group, an aryl group, an ester group, an amide group, and a phenyl group.

The modified organosiloxane to be used in the present disclosure more preferably has, at any or all of its side chain, one end, and both ends, at least one selected from the group consisting of a hydrogen atom, an amino group, a carboxyl group, an acrylic group, a carboxylic acid anhydride group, an alkyl group, a fluoroalkyl group, a perfluoroalkyl group, an ester group, an amide group, and a phenyl group.

The modified organosiloxanes to be used in the present disclosure still more preferably has, at any of its side chain, one end, and both ends, at least one selected from the group consisting of a hydrogen atom, an amino group, a carboxyl group, an acrylic group, a fluoroalkyl group, a phenyl group, and a carboxylic acid anhydride group.

Specific examples of the modified organosiloxane include methylhydrogenpolysiloxane, methylphenylpolysiloxane which is a copolymer of dimethylsiloxane and diphenylsiloxane, a carboxyl-modified polysiloxane, an amino-modified polysiloxane, an acrylic-modified polysiloxane, a methacrylic-modified polysiloxane, a fluoroalkyl group-modified polysiloxane, a carboxylic acid anhydride-modified polysiloxane, a polyether-modified polysiloxane, an epoxy-modified polysiloxane, and an epoxy-polyether-modified polysiloxane.

The polyether in the above-described polyether-modified polysiloxane is preferably a polyalkylene glycol, and examples of the polyalkylene glycol include polyethylene glycol, polypropylene glycol, polytrimethylene glycol, polytetramethylene glycol, polyhexamethylene glycol, and a polyalkylene glycol derived from a block or random copolymer of ethylene oxide and propylene oxide or the like.

As the organosiloxane to be used in the present disclosure, commercial organosiloxanes are available, such as polydimethly siloxanes (KF-96 and the like), methylphenylpolysiloxanes (KF-50 and the like), methylhydrogenpolysiloxane (KF-99), carboxyl group-modified polysiloxanes (X-22-3701E, X-22-162C, and the like), amino group-modified polysiloxanes (KF-868, KF-8012, KF-8008, and the like), acid anhydride-modified polysiloxanes (X-22-168 and the like), acrylic-modified polysiloxanes (X-22-2445 and the like), fluoroalkyl-modified polysiloxanes (X-22-822 and the like), and mercapto group-modified polysiloxanes (X-22-167B and the like) (all available from Shin-Etsu Chemical Co., Ltd.).

Other examples of the organosiloxane include WACKER AF98/1000, WACKER L655, and WACKER FINISH WT1270 manufactured by Wacker Asahi Kasei Silicone Co., Ltd., and TSF4704 manufactured by Momentive Performance Materials Inc.

In the present disclosure, as the organosiloxane, dimethylpolysiloxane, methylhydrogenpolysiloxane, methylphenylpolysiloxane, a carboxyl-modified polysiloxane, an amino-modified polysiloxane, an acrylic-modified polysiloxane, a carboxylic acid anhydride-modified polysiloxane, and a fluoroalkyl group-modified polysiloxane are suitable for use.

The above-described organosiloxane is preferably contained in an amount of less than 20% by mass of the entire composition. The organosiloxane in such an amount compounded is preferred in that it effectively suppresses an increase in dielectric loss tangent of the sheet due to moisture absorption, resulting in a sheet having a low dielectric loss tangent and a low coefficient of linear expansion. The amount compounded is more preferably 10% by mass or less, still more preferably 5% by mass or less, and particularly preferably 2% by mass or less. The lower limit of the amount of organosiloxane compounded is, on the other hand, preferably 0.01% by mass or more, more preferably 0.03% by mass or more, still more preferably 0.05% by mass or more, and particularly preferably 0.2% by mass or more. Such an amount compounded allows an increase in the dielectric loss tangent of the sheet due to moisture absorption to be effectively suppressed. The organosiloxane contained in an amount of 20% by mass or more of the entire composition tends to make the dielectric loss tangent and coefficient of linear expansion of the sheet large.

### (Inorganic Particle)

The inorganic particle to be used in the present disclosure is not limited, and examples thereof include one or more particles selected from silica, ceramics, talc, mica, aluminum oxide, zinc oxide, tin oxide, titanium oxide, calcium carbonate, calcium oxide, magnesium oxide, potassium titanate, a glass fiber, a glass flake, a glass bead, silicon carbide, calcium fluoride, boron nitride, barium sulfate, molybdenum disulfide, and a potassium carbonate whisker. They may be each used in combination of two or more thereof.

In achieving one of the objects of the present disclosure, which is to obtain a sheet with suppressed increase in dielectric loss tangent due to moisture absorption, the use of silica as an essential component is suitable in that it reduces the relative dielectric constant and dielectric loss tangent, as well as the coefficient of linear expansion. Therefore, it is preferable that the inorganic particles to be used in the present disclosure contain silica as an essential component.

In the case of the silica for use, it has a Si—O—Si—O surface, and the organosiloxane also has a Si—O—Si—O bond in its main backbone, and therefore the silica has higher compatibility with the organosiloxane than other inorganic particle, and a combination of the silica with the organosiloxane further enhances the effect of suppressing the moisture absorption.

The silica content in the inorganic particles is preferably 50% by mass or more, more preferably 65% by mass or more, and still more preferably 80% by mass or more.

The inorganic particle containing silica within the above-described range is advantageous in that the silica can reduce a dielectric loss tangent of the inorganic particle. The inorganic particle may also consist solely of silica.

The shape of the inorganic particle is not limited but is particularly preferably spherical. A spherical particle is preferable in terms of facilitating uniform processing upon drilling and having a small specific surface area, allowing reduction of a transmission loss.

It is preferable to use the spherical silica particle as the silica.

The spherical inorganic particle described above refers to a particle having a shape close to a perfect sphere, and specifically, its sphericity is preferably 0.80 or more, more preferably 0.85 or more, still more preferably 0.90 or more, and most preferably 0.95 or more. The sphericity is calculated by taking a photograph of the particle with an SEM and calculating a value from an area and an perimeter of the particle observed, by formula: (sphericity)={4π×(area)/(perimeter)²}. The closer the sphericity is to 1, the closer the particle is to a perfect sphere. Specifically, an average value measured for 100 particles is adopted using an image processing device (FPIA-3000 manufactured by Spectris PLC).

The inorganic particle to be used in the present disclosure preferably has a D90/D10 of 2 or more (preferably 2.3 or more, or 2.5 or more) and a D50 of 10 μm or less, when integrating its volume from the smallest particle size. Furthermore, the D90/D50 is preferably 1.5 or more (still more preferably 1.6 or more). The D50/D10 is preferably 1.5 or more (still more preferably 1.6 or more). Furthermore, the D50 is more preferably 5 μm or less. An inorganic particle with a small particle size can enter a space between inorganic particles with a large particle size, making it possible to achieve excellent filling properties and high flowability. In particular, the particle size distribution preferably has a higher degree of frequency of particle sizes on the small particle size side compared to a Gaussian curve.

The particle size can be measured using a laser diffraction/scattering particle size distribution measurement apparatus. Also, the presence of a coarse particle makes it difficult to form a thin sheet, so that a coarse particle having a particle size above a predetermined size is preferably removed using a filter or the like.

The inorganic particle preferably has water absorption of 1.0% or less, and still more preferably 0.5% or less. The water absorption of the inorganic particle within the above-described range can suppress moisture absorption of the sheet, allowing a sheet with suppressed increase in dielectric loss tangent due to moisture absorption to be obtained.

The water absorption of inorganic particle is based on the mass of the inorganic particle when dried. The water absorption is calculated by leaving a dry sample to stand at 40° C. and 80% RH for 1 hour and then measuring the content of moisture generated by heating to 200° C. using a Karl Fischer moisture analyzer.

The inorganic particle has an average particle size of, preferably, 0.5 μm or more. It is to be noted that the average particle size as used herein is the D50 value measured using a laser analysis particle size distribution analyzer.

The inorganic particle having an average particle size of less than 0.5 μm may cause aggregation thereof, as a result of which a sufficient effect may not be obtained.

The upper limit of the average particle size is not limited, but is preferably 250 μm or less, more preferably 100 μm or less, and still more preferably 50 μm or less.

The silica has a dielectric loss tangent at 10 GHz of preferably 0.0025 or less. Such a value is preferable in that the sheet has a low loss. The upper limit is more preferably 0.002, still more preferably 0.0015, and most preferably 0.0010.

The lower limit of the dielectric loss tangent is, on the other hand, preferably 0.00001.

In the present disclosure, the dielectric loss tangent of the silica measured at 10 GHz was measured using a cylindrical cavity resonator and a network analyzer, with a filler powder sample filled in a quartz tube and loaded into the resonator. The resonator properties (resonant frequency and Q value) were acquired before and after the sample load, from which the dielectric loss tangent was calculated. This measurement method is in accordance with the Japanese Industrial Standard JIS 2565 which is a measuring method for ferrite cores for microwave device, and a measurement is performed in an environment at room temperature of 25° C. and humidity of 40%.

Alternatively, the above-described parameters can also be measured by heating the sheet at 600° C. for 30 minutes in air to burn off the fluororesin, extracting the inorganic particle, and then using the above-described method.

The inorganic particle is preferably surface-treated. A preliminary surface treatment makes it possible to suppress aggregation of the inorganic particles and favorably disperse the inorganic particles in the resin composition.

This is also preferable in that the coefficient of linear expansion can be made low.

The surface treatment is not limited, and any publicly known surface treatment agent can be used. Specific examples thereof include treatment with silane coupling agents such as epoxy silane having a reactive functional group, amino silane, isocyanate silane, vinyl silane, acrylic silane, hydrophobic alkyl silane, phenyl silane, and fluorinated alkyl silane, plasma processing, and fluorination treatment.

Among the treatments, preferred is a treatment to surface-treat the inorganic particle with a silane coupling agent to coat them with the silane coupling agent.

Coating with the silane coupling agent is advantageous in that it can reduce the dielectric loss tangent.

Examples of the silane coupling agent include epoxy silanes, such as γ-glycidoxypropyltriethoxysilane and β-(3,4-epoxycyclohexyl)ethyltrimethoxysilane, amino silanes, such as aminopropyltriethoxysilane and N-phenylaminopropyltrimethoxysilane, an isocyanate silane such as 3-isocyanatopropyltrimethoxysilane, a vinyl silane such as vinyltrimethoxysilane, and an acrylic silane such as acryloxytrimethoxysilane.

The inorganic particle of the present disclosure are preferably surface-treated with a silane coupling agent with a mass proportion from 0.05 to 30% by mass.

The surface treatment is not limited and can be carried out by any known method. Specifically, for example, the inorganic particle can be treated with the silane coupling agent in a solution state where the silane coupling agent is dissolved in a solvent, or in a solvent-free state.

The spherical silica particle to be used described above may be a commercially available silica particle that satisfies the aforementioned properties. Examples of commercially available silica particle include DENKA Melting Silica FB Grade (manufactured by Denka Company Limited), DENKA Melting Silica SFP Grade (manufactured by Denka Company Limited), EXCELICA (manufactured by Tokuyama Corporation), high-purity synthetic spherical silica particles ADMAFINE (manufactured by Admatechs Co., Ltd.), ADMANANO (manufactured by Admatechs Co., Ltd.), and ADMAFUSE (manufactured by Admatechs Co., Ltd.).

The inorganic particle is preferably contained in a proportion of 40% by mass or more of the entire composition. Such an amount compounded results in low expansion while maintaining a low dielectric constant and a low loss, which is preferred. In addition, the inorganic particle allows the composition to have excellent moldability. The amount compounded is more preferably 50% by mass or more, and still more preferably 55% by mass or more. The upper limit of the amount of inorganic particle compounded is not limited, and is preferably 80% by mass or less, and still more preferably 70% by mass or less.

### (Fluororesin)

The fluororesin has low dielectric properties and is therefore suitable for use in order to achieve one of the objects of the present disclosure, which is to obtain a sheet with suppressed increase in dielectric loss tangent due to moisture absorption. Therefore, in such a purpose, the composition of the present disclosure preferably contains the fluororesin.

The fluororesin as can be used in the present disclosure is not limited, but examples thereof include polytetrafluoroethylene (PTFE), a tetrafluoroethylene [TFE]/hexafluoropropylene [HFP] copolymer [FEP], a TFE/alkyl vinyl ether copolymer [PFA], a TFE/HFP/alkyl vinyl ether copolymer [EPA], a TFE/chlorotrifluoroethylene [CTFE] copolymer, a TFE/ethylene copolymer [ETFE], polyvinylidene difluoride [PVdF], and tetrafluoroethylene with a molecular weight of 300,000 or less [LMW-PTFE]. These may be used singly or two or more thereof may be mixed and used.

In particular, the fluororesin is preferably perfluorinated fluororesin.

Among these, Polytetrafluoroethylene resin (PTFE) is particularly preferred from the viewpoint of low dielectric properties. The PTFE preferably has fibrillating ability. The PTFE having fibrillating ability means a PTFE that can be extruded in paste form from unsintered polymer powder thereof.

The PTFE may be modified polytetrafluoroethylene (hereinafter referred to as modified PTFE), homopolytetrafluoroethylene (hereinafter referred to as homo-PTFE), or a mixture of modified PTFE and homo-PTFE. It is to be noted that from the viewpoint of favorably maintaining formability of the polytetrafluoroethylene, the proportion of the content of the modified PTFE in polymer PTFE is preferably 10% by weight or more and 98% by weight or less and more preferably 50% by weight or more and 95% by weight or less. The homo-PTFE is not limited, and the following homo-PTFEs can be suitably used, which have been disclosed in Japanese Patent Laid-Open No. 53-60979, Japanese Patent Laid-Open No. 57-135, Japanese Patent Laid-Open No. 61-16907, Japanese Patent Laid-Open No. 62-104816, Japanese Patent Laid-Open No. 62-190206, Japanese Patent Laid-Open No. 63-137906, Japanese Patent Laid-Open No. 2000-143727, Japanese Patent Laid-Open No. 2002-201217, International Publication No. WO 2007/046345, International Publication No. WO 2007/119829, International Publication No. WO 2009/001894, International Publication No. WO 2010/113950, International Publication No. WO 2013/027850, and the like. Among these, homo-PTFEs having a high degree of stretchability are preferred, which have been disclosed in Japanese Patent Laid-Open No. 57-135, Japanese Patent Laid-Open No. 63-137906, Japanese Patent Laid-Open No. 2000-143727, Japanese Patent Laid-Open No. 2002-201217, International Publication No. WO 2007/046345, International Publication No. WO 2007/119829, International Publication No. WO 2010/113950, and the like.

The modified PTFE is composed of TFE and a monomer other than TFE (hereinafter referred to as a modifying monomer). Examples of the modified PTFE include but are not limited to modified PTFE in which PTFE has been uniformly modified with the modifying monomer, modified PTFE in which PTFE has been modified at the beginning of the polymerization reaction, and modified PTFE in which PTFE has been modified at the end of the polymerization reaction. The modified PTFE is preferably a TFE copolymer obtained by subjecting TFE to polymerization with a trace amount of a monomer other than TFE, within a range that does not significantly impair the properties of a TFE homopolymer. The following modified PTFEs can be suitably used, such as those disclosed in, for example, Japanese Patent Laid-Open No. 60-42446, Japanese Patent Laid-Open No. 61-16907, Japanese Patent Laid-Open No. 62-104816, Japanese Patent Laid-Open No. 62-190206, Japanese Patent Laid-Open No. 64-1711, Japanese Patent Laid-Open No. 2-261810, Japanese Patent Laid-Open No. 11-240917, Japanese Patent Laid-Open No. 11-240918, International Publication No. WO 2003/033555, International Publication No. WO 2005/061567, International Publication No. WO 2007/005361, International Publication No. WO 2011/055824, International Publication No. WO 2013/027850, and the like. Among these, preferred are modified PTFEs having a high degree of stretchability, such as those disclosed in Japanese Patent Laid-Open No. 61-16907, Japanese Patent Laid-Open No. 62-104816, Japanese Patent Laid-Open No. 64-1711, Japanese Patent Laid-Open No. 11-240917, International Publication No. WO 2003/033555, International Publication No. WO 2005/061567, International Publication No. WO 2007/005361, International Publication No. WO 2011/055824, and the like.

The modified PTFE includes a TFE unit based on TFE and a modifying monomer unit based on the modifying monomer. The modifying monomer unit is a portion of the molecular structure of the modified PTFE and is derived from the modifying monomer. The modified PTFE preferably contains a modifying monomer unit in an amount of 0.001 to 0.500% by weight and more preferably 0.01 to 0.30% by weight, of the total monomer unit. The total monomer unit is a portion derived from all monomers in the molecular structure of the modified PTFE.

The modifying monomer is not limited as long as it can be copolymerized with TFE, and examples thereof include a perfluoroolefin such as hexafluoropropylene (HFP); a chlorofluoroolefin such as chlorotrifluoroethylene (CTFE); hydrogen-containing fluoroolefins such as trifluoroethylene and vinylidene difluoride (VDF); perfluorovinyl ether; a perfluoroalkylethylene (PFAE), and ethylene. The modifying monomer to be used may be one type or a plural types thereof.

The perfluorovinyl ether is not limited, and examples thereof include an unsaturated perfluoro compound represented by the following general formula (1):

CF₂═CF—ORf (1)

(wherein Rf represents a perfluoro organic group.)

The perfluoro organic group as used herein is an organic group in which all hydrogen atoms bonded to carbon atoms are replaced with fluorine atoms. The perfluoro organic group may have an ether oxygen.

An example of the perfluorovinyl ether includes a perfluoro(alkyl vinyl ether) (PAVE) in which Rf in the general formula (1) described above is a perfluoroalkyl group having 1 to 10 carbon atoms. The number of carbon atoms in the perfluoroalkyl group is preferably 1 to 5. Examples of the perfluoroalkyl group in a PAVE include a perfluoromethyl group, a perfluoroethyl group, a perfluoropropyl group, a perfluorobutyl group, a perfluoropentyl group, and a perfluorohexyl group. A preferred PAVE is perfluoropropyl vinyl ether (PPVE) and perfluoromethyl vinyl ether (PMVE).

The perfluoroalkyl ethylene (PFAE) is not limited, and examples thereof include perfluorobutyl ethylene (PFBE) and perfluorohexyl ethylene (PFHE).

The modifying monomer in the modified PTFE is preferably at least one selected from the group consisting of HFP, CTFE, VDF, a PAVE, a PFAE and ethylene.

The fluororesin described above is preferably non-melt-processible. The phrase non-melt-processible means that a resin does not have sufficient flowability even when heated at its melting point or higher, and cannot be molded by melt forming techniques commonly used for resins. PTFE corresponds thereto.

In the present disclosure, it is preferable to use such a non-melt-processible fluororesin and form it into a sheet by a forming method for fibrillating it. This forming method will be described later.

The PTFE preferably has an SSG of 2.0 to 2.3. The use of such PTFE facilitates a PTFE film having high strength (cohesion strength and puncture strength per unit thickness) to be obtained. PTFE with a large molecular weight has long molecular chains, making it less likely to form a structure of molecular chains regularly arranged. In this case, an amorphous portion elongates, resulting in an increase in the degree of entanglement between molecules. It is considered that the high degree of entanglement between molecules is less likely to allow a PTFE film to deform under an applied load and therefore to exhibit excellent mechanical strength. Also, using PTFE with a large molecular weight facilitates a PTFE film having a small average pore size to be obtained.

The lower limit of the SSG is more preferably 2.05 and still more preferably 2.1. The upper limit of the SSG is more preferably 2.25 and still more preferably 2.2.

The standard specific gravity [SSG] is measured by fabricating a sample in accordance with ASTM D-4895-89 and measuring the specific gravity of the obtained sample by a water displacement method.

In the present disclosure, the molecular weight (number-average molecular weight) of the PTFE constituting the PTFE powder is preferably in the range of, for example, from 2 to 12 million. The lower limit value of the molecular weight of the PTFE may be 3 million or 4 million. The upper limit value of the molecular weight of the PTFE may be 10 million.

A method for measuring the number-average molecular weight of the PTFE includes a method for determining the number-average molecular weight using the standard specific gravity (SSG) and a method for determining the number-average molecular weight using a dynamic viscoelasticity upon melting. The method for determining the number-average molecular weight using the standard specific gravity can be performed by a water displacement method in accordance with ASTM D-792 using a sample formed in accordance with ASTM D-4895 98. The method for measuring the number-average molecular weight using a dynamic viscoelasticity is explained, for example, by S. Wu in Polymer Engineering & Science, 1988, Vol. 28, 538 and in the same publication, 1989, Vol. 29, 273.

The PTFE preferably has a refractive index in the range of 1.2 to 1.6. With such a refractive index, the PTFE has a low dielectric constant, which is preferable in this regard. The refractive index can be adjusted to within the range described above by a method of adjusting the polarizability or flexibility of the main chain or the like. The lower limit of the refractive index is more preferably 1.25, more preferably 1.30, and most preferably 1.32. The upper limit of the refractive index is more preferably 1.55, more preferably 1.50, and most preferably 1.45.

The refractive index is the value measured using a refractometer (Abbemat 300).

Also, the PTFE preferably has the maximum endothermic peak temperature (crystalline melting point) of 340±7° C.

The PTFE may be low-melting-point PTFE having the maximum peak temperature of 338° C. or lower on an endothermic curve on a crystalline melting curve measured by a differential scanning calorimeter, or high-melting-point PTFE having the maximum peak temperature of 342° C. or higher on an endothermic curve on a crystalline melting curve measured by a differential scanning calorimeter.

The low-melting-point PTFE powder is powder produced by a polymerization using an emulsion polymerization method, and has the maximum endothermic peak temperature (crystalline melting point), a dielectric constant (ε) of 2.08 to 2.2, and a dielectric loss tangent (tan δ) of 1.9×10⁻⁴ to 4.0×10⁻⁴. Examples of a commercially available product thereof include POLYFLON Fine Powder F201, F203, F205, F301, and F302 manufactured by Daikin Industries, Ltd.; CD090 and CD076 manufactured by Asahi Glass Co., Ltd.; and TF6C, TF62, and TF40 manufactured by Dupont De Nemours Inc.

The high melting point PTFE powder is also powder produced by a polymerization using an emulsion polymerization method, and has the maximum endothermic peak temperature (crystalline melting point) described above, a dielectric constant (ε) of 2.0 to 2.1, and a dielectric loss tangent (tan δ) of 1.6×10⁻⁴ to 2.2×10⁻⁴, which are overall low. Examples of a commercially available product thereof include POLYFLON Fine Powder F104 and F106 manufactured by Daikin Industries, Ltd.; CD1, CD141, and CD123 manufactured by Asahi Glass Co., Ltd.; and TF6 and TF65 manufactured by DuPont De Nemours Inc.

It is to be noted that an average particle size of powder in which both PTFE polymer particles have undergone secondary aggregation is usually preferably 250 to 2,000 μm. In particular, granulated powder obtained by granulation using a solvent is preferred from the viewpoint of improving flowability when filled in a mold upon preliminary forming.

PTFE in powder form that satisfies the aforementioned parameters can be obtained using conventional production methods. For example, it may be produced by following the production methods described in International Publication No. WO 2015-080291 and International Publication No. WO 2012-086710.

### (Resin Other Than Fluororesin)

The composition of the present disclosure may use a resin other than the fluororesin as a resin.

Examples of the resin other than the fluororesin include a cellulose triacetate film, a cycloolefin polymer, a cycloolefin copolymer, polyethylene terephthalate, polyethylene naphthalate, polycarbonate, transparent polyimide, thermoplastic polyimide, polyacrylate, polymethyl methacrylate, polystyrene, polyvinyl chloride, syndiotactic polystyrene, polymethylpentene, an epoxy resin, an alicyclic epoxy resin, a silicone resin (excluding those included in the above-described organosiloxanes), polyphenylene ether, modified polyphenylene ether, polyurethane, a phenolic resin, a bismaleimide resin, a cyanate resin, a urea resin, a melamine resin, and an unsaturated polyester resin.

### (Composition)

The composition of the present disclosure contains the aforementioned organosiloxane, inorganic particle, and fluororesin or resin other than the fluororesin.

The composition of the present disclosure may contain another component other than these, if necessary, but is preferably substantially composed of the organosiloxane, inorganic particle, and fluororesin or resin other than the fluororesin. It is particularly preferred that the composition is composed substantially of the organosiloxane, inorganic particle, and fluororesin.

In the present disclosure, “substantially” means that a component other than the fluororesin particle, the resin other than the fluororesin, the inorganic particle, and the organosiloxane, is contained in a proportion of 10% by mass or less of the composition. Furthermore, the composition of the present disclosure preferably consists solely of the organosiloxane, inorganic particle, and fluororesin or the resin other than the fluororesin. It is particularly preferred that the composition consists solely of the organosiloxane, inorganic particle, and fluororesin.

### (Method for Producing Composition)

The composition of the present disclosure can be obtained, for example, by mixing each component of the aforementioned resin particle, inorganic particle, and organosiloxane by stirring or the like.

The mixing conditions are not limited, but they can be mixed, for example, by stirring them at room temperature using a mixer such as a Wonder Crusher. A too short stirring time may result in insufficient mixing, while a too long stirring time may cause molecular scission and fiberization of the resin, and therefore it is preferable to stir the composition for an appropriate time. Also, stirring it at a low temperature in the presence of dry ice can prevent molecular scission and fiberization of the resin, also allowing them to be mixed.

For example, a composition can be obtained under the following conditions, and a sheet can be obtained from the obtained composition by a method for producing the sheet as will be described below.

In the case of producing a sheet by powder rolling forming, it is preferable to weigh out, for example, each component of the resin particle, inorganic particle, and organosiloxane in the desired proportions and stir them in a Wonder Crusher at room temperature for a time from 10 seconds to 10 minutes. In addition, the stirring may be performed once or separately performed in two or more times.

In the case of producing a sheet by paste extrusion forming, it is preferable to weigh out the desired amount of each component of the resin particle, inorganic particle, and organosiloxane and mix them in a mixer in the presence of dry ice. The temperature during mixing is preferably −10° C. or lower.

It is also preferable to add an auxiliary agent for extrusion such as oil (IP Solvent 2028) in a proportion of 18 to 23% by mass to the resulting mixed powder, mix them, and then allow the mixture to be aged for approximately 5 hours.

### (Sheet)

The composition of the present disclosure is suitable for use in forming a sheet.

The present disclosure is also a sheet composed of the composition.

The sheet of the present disclosure can have suppressed water absorption and moisture absorption. The water absorption is preferably 0.1 wt. % or less, still more preferably 0.08 wt. % or less, and most preferably 0.04 wt. % or less.

The measured water absorption is a value calculated in accordance with IPC TM650 2.6.2.1.

The sheet of the present disclosure preferably has an increased value of moisture content of 60 ppm or less when stored for one week in an environment of 30° C. and 90% RH. When the increased value of moisture content is 60 ppm or less, the moisture absorption can be said to be suppressed. The increased value of moisture content is more preferably 30 ppm or less, and still more preferably 15 ppm or less.

The increased value of moisture content is a value calculated by measuring moisture generated by heating the sheet at 250° C. using a Karl Fischer moisture analyzer.

The sheet of the present disclosure can also reduce a surface tension for liquid repellency. The surface tension for liquid repellency can be evaluated using the following method.

The sheet was immersed in a “wetting tension test mixture” manufactured by Wako Pure Chemical Industries, Ltd. at room temperature for 1 minute, then washed with distilled water, and whether the wetting tension test mixture had penetrated the sheet or not was visually confirmed. Wetting tension test mixtures No. 22.6 to 70.0 were used, and the critical tension for liquid repellency was determined by a value of the test liquid with the lowest surface tension among the wetting tension test mixtures that did not penetrate the sheet.

Wetting tension test mixtures with a variety of wetting tensions (23° C.) are available, and each contains a colorant, allowing visual confirmation of whether or not it will penetrate the test specimen.

The critical tension for liquid repellency is preferably 37 mN/M or less, still more preferably 32 mN/M, and most preferably 22.6 mN/M.

The sheet of the present disclosure, particularly when using the composition containing the fluororesin, suppresses fluctuations in a dielectric loss tangent due to moisture absorption.

The sheet of the present disclosure preferably has a relative dielectric constant at 10 GHz of 3.5 or less. The relative dielectric constant value within such a range is preferable in terms of giving a low dielectric loss.

The upper limit of the relative dielectric constant is more preferably 3.2, and still more preferably 3.1. Meanwhile, the lower limit of the relative dielectric constant is preferably 2.0, and more preferably 2.5.

The sheet of the present disclosure preferably has a dielectric loss tangent at 10 GHz of 0.0015 or less. The dielectric loss tangent within this range is preferable in terms of minimizing an electrical signal loss in a circuit. The dielectric loss tangent is more preferably 0.0012 or less, and still more preferably 0.0011 or less. Meanwhile, the lower limit of the dielectric loss tangent is preferably 0.00001.

The relative dielectric constant (Dk) and dielectric loss tangent (Df) of the sheet disclosed herein at 10 GHz are values determined by measuring Dk and Df at 25° C. and 10 GHz using a split-cylinder dielectric constant/dielectric loss tangent measuring apparatus (manufactured by EM Lab P&K).

The sheet of the present disclosure preferably has an increased rate of the dielectric loss tangent of 30% or less when stored for 24 hours in an environment of 30° C. and 90% RH. The increased rate of the dielectric loss tangent is more preferably 20% or less, and still more preferably 12% or less.

The increased rate of the dielectric loss tangent is the value calculated using the following formula by placing each sample in a constant-humidity and temperature chamber maintained at 30° C. and 90% RH, tracking a change in a dielectric loss tangent after 24 hours, and then calculating the value.

Increased rate (%)=(dielectric loss tangent after 24 hours−dielectric loss tangent before constant humidity test)/dielectric loss tangent before constant humidity test×100

The sheet of the present disclosure preferably has a coefficient of linear expansion (CTE) of 200 ppm/K or less.

The CTE within this range is preferable in that a sheet with low shrinkage and excellent dimensional stability results. The upper limit is more preferably 150 ppm/K, still more preferably 100 ppm/K, and most preferably 70 ppm/K. The lower limit is not limited, but is preferably 10 ppm/K, and still more preferably 20 ppm/K.

The coefficient of linear expansion as used herein is the value determined by the procedures whereby the sheet was cut out to prepare a sample piece measuring 20 mm in length, 5 mm in width, and 150 μm in thickness, underwent a TMA measurement in tension mode using a TMA-7100 (manufactured by Hitachi High-Tech Science Corporation), a distance between chucks was set to 10 mm, the sample was applied a load of 49 mN while heated from 0 to 150° C. at a heating rate of 2° C./min, and the coefficient of linear expansion was determined from the amounts of displacement of the sample.

In the present disclosure, in a case in which the modified organosiloxane is used as the organosiloxane, a sheet with suppressed moisture absorption and suppressed decomposition of the organosiloxane during sintering can be provided.

The sheet of the present disclosure preferably has a thickness of less than 300 μm. Even though the sheet of the present disclosure is thin, it can adequately achieve its intended purpose. From this perspective, it has a thickness of more preferably less than 200 μm, and still more preferably less than 150 μm. In addition, in a case in which the sheet is capable of being processed in a thickness of 100 μm or less, if necessary, it can be widely applied to substrates of various thicknesses, which is preferable.

### (Method for Producing Sheet)

The sheet of the present disclosure can be obtained by forming the composition obtained by mixing the aforementioned resin particle, inorganic particle, and organosiloxane. The method of production is not limited, but is suitably performed by paste extrusion forming, powder rolling forming, or the like.

The present disclosure is also a method for producing the aforementioned sheet, characterized by forming the composition obtained by mixing the fluororesin particle, inorganic particle, and organosiloxane.

The method for producing a sheet of the present disclosure preferably includes forming by using a composition substantially composed of the fluororesin particle, inorganic particle, and an organosiloxane.

As described above, it is preferable to use, as the fluororesin to be used in the sheet of the present disclosure, a non-melt-processible fluororesin. When such a fluororesin is used and formed into a sheet, it is preferable to form it into a sheet by fibrillating powdered PTFE as a raw material.

It is preferable to use the powdered PTFE having a primary particle size of 0.05 to 10 μm. Using such powder has an advantage of excellent moldability and dispersibility. It is to be noted that the primary particle size as used herein is a value measured in accordance with ASTM D 4895.

The powdered PTFE contains a polytetrafluoroethylene resin having a secondary particle size of 500 μm or more in an amount of preferably 50% by mass or more and more preferably 80% by mass or more. The PTFE having a secondary particle size of 500 μm or more within the above range, has an advantage of being capable of fabricating a mixture sheet with high strength.

Using the PTFE having a secondary particle size of 500 μm or more enables a mixture sheet with lower resistance and greater toughness to be obtained.

The lower limit of the secondary particle size is more preferably 300 μm and still more preferably 350 μm. The upper limit of the secondary particle size is more preferably 700 μm or less and still more preferably 600 μm or less. The secondary particle size can be determined, for example, by a sieving method or the like.

The powdered PTFE described above can provide a sheet with higher strength and excellent homogeneity, so that an average primary particle size thereof is preferably 50 nm or more, more preferably 100 nm or more, still more preferably 150 nm or more, and particularly preferably 200 nm or more.

The larger the average primary particle size of PTFE is, the more inhibited an increase in paste extrusion pressure upon paste extrusion forming using the powder will be, also resulting in excellent moldability. The upper limit of the average primary particle size of PTFE is not limited, but it may be 500 nm. From the viewpoint of productivity in a polymerization process, it is preferably 350 nm.

The average primary particle size can be determined by preparing a calibration curve of a transmission of projected light of 550 nm relative to a unit length of an aqueous dispersion obtained by using an aqueous dispersion of PTFE obtained by polymerization and adjusting its polymer concentration to 0.22% by mass, and an average primary particle size determined by measuring a unidirectional diameter of the particle observed in a photograph of the particle by a transmission electron microscope, and then measuring the transmission of the aqueous dispersion to be measured, based on the calibration curve.

The PTFE to be used in the present disclosure may have a core-shell structure. An example of the PTFE having a core-shell structure includes modified polytetrafluoroethylene which contains a core of high molecular weight polytetrafluoroethylene in the particle and a shell of lower molecular weight polytetrafluoroethylene or modified polytetrafluoroethylene. An example of such modified polytetrafluoroethylene includes the polytetrafluoroethylene described in Japanese Translation of PCT International Application Publication No. 2005-527652.

Specific methods of paste extrusion forming and powder rolling forming are not limited, and a general method will be described below.

### (Paste Extrusion Forming)

The method for producing the sheet may also include a step (1a) of mixing the composition containing fluororesin powder obtained using a hydrocarbon-based surfactant, inorganic particle, and organosiloxane with an auxiliary agent for extrusion; a step (1b) of subjecting the obtained mixture to paste extrusion forming; a step (1c) of rolling the extrudate obtained by the extrusion forming; a step (1d) of drying the rolled sheet; and a step (1e) of sintering the dried sheet to obtain a formed article.

The paste extrusion forming may also be performed by adding a conventional known additive, such as a pigment, to the composition.

The auxiliary agent for extrusion is not limited, and any publicly known agent may be used. Examples thereof include hydrocarbon oil and the like.

### (Powder Rolling Forming)

The sheet can also be formed by powder rolling forming. The powder rolling forming is a method for applying shear force to a resin powder followed by fibrillation thereof, and thus forming it into a sheet. This method may include the step of sintering the sheet thereafter to obtain a formed article.

More specifically, the sheet can be obtained by a production method including a step (1) of applying shear force to the composition containing the fluororesin powder, inorganic particle, and organosiloxane while mixing the composition;
a step (2) of forming the mixture obtained in the step (1) into a bulk form; and
a step (3) of rolling the mixture in the bulk form obtained in the step (2) into a sheet shape.

It is to be noted that in the case of forming the sheet using such powder rolling forming, it is preferable to mix and form only the fluororesin powder, inorganic particle, and organosiloxane.

The method may further include a step (4) of sintering the sheet-like product obtained above at a temperature from 200 to 400° C. for a time from 1 to 60 minutes.

Also, step (2) may also be omitted.

The sheet of the present disclosure may also be formed by a casting method whereby a solution or dispersion containing the fluororesin, inorganic particle, and organosiloxane is prepared, and a substrate is coated with the solution or dispersion followed by drying to form a sheet.

It is to be noted that in the case of employing a sintering step at a temperature of 300° C. or higher upon production of the sheet, a sintering time of, for example, approximately 30 minutes or less allows the organosiloxane to be only partially decomposed, resulting in a sheet having the effects of the present disclosure.

### (Laminate)

The sheet of the present disclosure can be stacked with a metal layer and used, for example, as a sheet of a circuit board. An example of the laminate includes a metal-clad laminate in which a metal layer adheres to one or both sides of the aforementioned sheet.

The present disclosure is also a metal-clad laminate composed of a metal layer and the above-described sheet as essential layers.

As described above, the sheet containing the fluororesin of the present disclosure can be particularly suitably used in applications of circuit board and can therefore be suitably used as such a metal-clad laminate.

Examples of the metal layer include copper foil, gold foil, silver foil, platinum foil, and ruthenium foil. Of these, copper foil is preferred due to its low conductor loss.

The copper foil described above preferably has an Rz of 1.6 μm or less. The sheet of the present disclosure is also excellent in adhesiveness to copper foil with high degree of smoothness of an Rz of 1.6 μm or less. Furthermore, the Rz of at least a surface of the copper foil adhering to the aforementioned sheet is 1.6 μm or less and the Rz value of the other surface is not limited. The Rz is the sum of a value of the highest portion (maximum peak height: Rp) and a value of the deepest portion (maximum valley depth: Rv). The surface roughness is a ten-point average roughness stipulated in JIS-B0601. The Rz as used herein is the value measured using a surface roughness meter (product name: SURFCOM 470A, manufactured by Tokyo Seimitsu Co., Ltd.) with a measurement length of 4 mm.

A thickness of the copper foil is not limited, and is preferably in the range of 1 to 100 μm, more preferably in the range of 5 to 50 μm, and still more preferably 9 to 35 μm.

The copper foil is not limited, and specific examples thereof include rolled copper foil and electrolytic copper foil.

The copper foil having an Rz of 1.6 μm or less is not limited, and commercially available products can be used. An example of commercially available copper foil having an Rz of 1.6 μm or less includes electrolytic copper foil CF-T9DA-SV-18 (thickness 18 μm/Rz 0.85 μm) (manufactured by Fukuda Metal Foil Powder Co., Ltd.).

The copper foil may have been subjected to surface treatment in order to enhance the adhesive strength to the sheet of the present disclosure.

The surface treatment may be, but is not limited to, silane coupling processing, plasma processing, corona processing, UV processing, electron beam processing, and the like, and a reactive functional group of the silane coupling agent is not limited, but from the viewpoint of adhesiveness to a resin substrate, the silane coupling agent preferably has at least one selected from an amino group, a (meth)acrylic group, a mercapto group, and an epoxy group, at an end of the agent. Also, a hydrolyzable group may be, but is not limited to, alkoxy groups such as a methoxy group and an ethoxy group. The copper foil to be used in the present disclosure may be copper foil in which an anti-corrosion layer (for example, an oxide film such as a chromate), a heat-resistant layer, or the like, has been formed.

Surface-treated copper foil having a surface treating layer with the silane compound described above on a surface of the copper foil can be produced by preparing a solution containing a silane compound and then surface-treating the copper foil with this solution.

The copper foil may have a roughening-treated layer on its surface from the viewpoint of enhancing the adhesiveness to a sheet.

Incidentally, in a case in which roughening processing may deteriorate the performance required in the present disclosure, the number of roughened particles to be electrodeposited on a surface of the copper foil can be reduced if necessary, or the copper foil may be used in a manner not to undergo roughening processing.

From the viewpoint of improving various properties, one or more layers selected from the group consisting of a heat-resistant treatment layer, an anti-corrosion treatment layer, and a chromate treatment layer may be disposed between the copper foil and a surface treating layer. These layers may be each a single layer or a multilayer.

The metal-clad laminate of the present disclosure may be those further having a layer other than the metal layer and the sheet of the present disclosure.

The layer other than the metal layer and the sheet is preferably a layer composed of at least one selected from the group consisting of polyimide, modified polyimide, a liquid crystal polymer, polyphenylene sulfide, a cycloolefin polymer, polystyrene, an epoxy resin, bismaleimide, a polyphenylene oxide, a modified polyphenylene ether, a polyphenylene ether, and polybutadiene.

The layer other than these metal layer and sheet is not limited as long as it is composed of the aforementioned resins. Also, a thickness of the layer other than the metal layer and the sheet is preferably within the range of 12.5 to 260 μm.

In the metal-clad laminate of the present disclosure, a metal layer may be formed on one or both sides of a sheet. Examples of a method for forming the metal layer include a method for stacking metal layer on a surface of the roll sheet (for allowing metal foil to adhere thereon), a vapor deposition method, a plating method, and the like. An example of the method for stacking metal layer includes a method using heat press. An example of a heat press temperature upon heat press includes a temperature between the melting point of the sheet −150° C. and the melting point of the sheet +40° C. A heat press time is, for example, 1 to 30 minutes. The pressure of the heat press is 0.1 to 10 MPa, thereby the laminate can be produced.

The sheet included in the metal-clad laminate of the present disclosure may contain at least one selected from the group consisting of formaldehyde, formic acid, and hexamethylcyclotrisiloxane, octamethylcyclotetrasiloxane, and decamethylcyclopentasiloxane. In producing a metal-clad laminate, the processing temperature may reach 300° C. or higher, causing decomposition of the organosiloxane contained in the sheet. When decomposed, the organosiloxane generates formaldehyde, formic acid, and hexamethylcyclotrisiloxane, octamethylcyclotetrasiloxane, and decamethylcyclopentasiloxane, which are derived from organic groups of the organosiloxane, as a result of which the sheet included in the metal-clad laminate contains at least one selected from the group consisting of formaldehyde, formic acid, and hexamethylcyclotrisiloxane, octamethylcyclotetrasiloxane, and decamethylcyclopentasiloxane.

In the present disclosure, the presence of formaldehyde, formic acid, hexamethylcyclotrisiloxane, octamethylcyclotetrasiloxane, and decamethylcyclopentasiloxane in the sheet included in the metal-clad laminate can be confirmed by heating the sheet to 360° C., collecting a generated gas, and analyzing the gas using thermal desorption GCMS.

In a case in which the sheet included in the metal-clad laminate contain, for example, 50 ppm or more of at least one selected from the group consisting of formaldehyde, formic acid, and hexamethylcyclotrisiloxane, octamethylcyclotetrasiloxane, and decamethylcyclopentasiloxane, the organosiloxane can be said to be included in the sheet used upon production of the metal-clad laminate.

The metal-clad laminate of the present disclosure is not limited in its application and is suitably used as a circuit board.

The present disclosure is also a circuit board having the above-described metal-clad laminate.

A circuit board is a platy component that electrically connects electronic components such as a semiconductor and a capacitor chip while simultaneously arranging and fixing them in a limited space. The configuration of a circuit board formed of the metal-clad laminate of the present disclosure is not limited. The circuit board may be any one of a rigid board, a flexible board, or a rigid-flexible board. The circuit board may be any one of a single-sided board, a double-sided board, or a multilayer board (such as a build-up board). In particular, a flexible board or a rigid board can be suitably used. It is particularly suitable for use as a printed circuit board for high frequencies of 10 GHz or higher.

In the present disclosure, examples of the high-frequency circuit include not only a circuit that transmits only high-frequency signals, but also a circuit in which a transmission line transmitting signals other than high-frequency signals is also arranged on the same plane, such as a transmission line that converts high-frequency signals to low-frequency signals and outputs the generated low-frequency signals to an outside, a transmission line that supplies power supplied to drive high-frequency compatible components, and the like. Also, it can also be used as a circuit board for antennas, filters, and the like.

The present disclosure is also an antenna formed of the circuit board. It is particularly suitable for use as a millimeter wave antenna for mobility applications such as automobiles and aircraft.

The circuit board is not limited and can be produced by a general method using the aforementioned metal-clad laminate.

The sheet and metal-clad laminate of the present disclosure are used as electrical and electronic components. Examples thereof include antennas to be used in electronic equipment and communication equipment such as an ETC, GPS, wireless LAN, and a mobile phone, a high-speed transmission connector, a CPU socket, millimeter-wave and quasi-millimeter-wave radars such as collision prevention radars, an RFID tag, a capacitor, an inverter component, a coating material of cables, an insulating material for a secondary battery such as a lithium-ion battery, and a speaker diaphragm.

Examples of the high-speed communication compatible substrate include a base station antenna substrate, an antenna distribution substrate, a substrate for an RRH (Remote Radio Head), which is a radio portion of a wireless base station, a substrate for a control portion or a baseband portion (BBU: Base Band Unit) of a wireless base station, a high-speed communication transceiver substrate, an RNC (Radio Network Controller) substrate, a high-speed transmitter substrate, a high-speed receiver substrate, a substrate for high-speed signal multiplexing circuits, a substrate for Wi-Fi using a 60 GHz band, and a data transfer substrate to be used in data center servers. Further examples of the high-speed communication compatible substrate include an antenna substrate, such as a substrate for massive MIMO antennas aimed at high-capacity communication required by standards beyond 5G. A further example thereof also includes a receiving antenna for wireless power transmission by microwave space propagation. The sheet of the present disclosure has a favorable adhesiveness with unroughened copper foil, which has a low transmission loss, so that in a case in which a copper-clad laminate including the sheet of the present disclosure and unroughened copper foil is processed to produce an antenna, the gain is improved, making it particularly suitable for antennas.

The sheet of the present disclosure can be used not only as an insulator for substrates, but also as an insulating material for signal line covering. For example, it can be used as materials for insulating coating (for example, insulating tubes) for a waveguide that transmits high-speed signals, a QSFP cable for high-speed LANs, a coaxial cable compatible for high-speed communication (for example, SFP+a cable, QSFP+a cable, and the like), a coaxial cable for low losses, and the like.

When using such high frequencies, a material to be used in an electrical component such as a connector and communication equipment such as a casing, requires stable electrical properties, such as a low relative dielectric constant (εr) and a low dielectric loss tangent (tan δ). The sheet of the present disclosure can also be used as an insulating material for such materials.

The sheet of the present disclosure can also be used as an insulating material for connector printed wiring boards that needs to be soldered. The sheet of the present disclosure has excellent heat resistance, making it unlikely to cause a problem even at an elevated temperature upon soldering.

In a dielectric waveguide line, a material with a low dielectric loss is required in order to transmit high-frequency millimeter waves or submillimeter waves with a low loss. The sheet of the present disclosure can also be used as an insulation material for dielectric waveguide lines that transmit millimeter waves or submillimeter waves. Examples of the dielectric waveguide line include a cylindrical dielectric line, a rectangular dielectric line, an elliptical dielectric line, a tubular dielectric line, an image line, an insular image line, a trapped image line, a rib guide, a strip dielectric line, an inverted strip line, an H guide, and a non-radiative dielectric line (NRD guide).

In the present disclosure, the mobility refers to all means and methods related to movement and transportation, including automobiles in general, such as a private car, a bus, a taxi, and a truck, as well as two-wheeled vehicles such as a motorcycle, a bicycle, and a moped, a train, a senior car, and a compact one-seater personal mobility vehicle. Also, the mobility is not necessarily limited to means such as vehicles that move on land and may be means that move through the air or water.

A laminate for a circuit board may be a laminate having a copper foil layer, the aforementioned sheet, and a substrate layer. The substrate layer is not limited but preferably has a fabric layer composed of glass fibers and a resin film layer.

The fabric layer composed of glass fibers described above is a layer composed of glass cloth, a glass nonwoven fabric, or the like. Commercially available glass cloth can be used, and glass cloth treated with a silane coupling agent is preferred in order to enhance the affinity with a fluororesin. Examples of glass cloth materials include E-glass, C-glass, A-glass, S-glass, D-glass, NE-glass, and low-dielectric-constant glass, and preferred are E-glass, S-glass, and NE-glass due to their availability. A weaving method may be either plain weave or twill weave. The glass cloth typically has a thickness of 5 to 90 μm, preferably 10 to 75 μm, but it is preferable to use one thinner than the fluororesin film to be used.

The laminate described above may also use a glass nonwoven fabric as a fabric layer composed of glass fibers. The glass nonwoven fabric is a fabric in which glass staple fibers are bonded together with a small amount of binder compound (resin or inorganic material), and a fabric maintaining its shape by entangling glass staple fibers without using a binder compound, which are commercially available. The diameter of the glass staple fiber is preferably 0.5 to 30 μm and the fiber length is preferably 5 to 30 mm. Specific examples of the binder compound include resins such as an epoxy resin, an acrylic resin, cellulose, a polyvinyl alcohol, and a fluororesin, as well as an inorganic substance such as a silica compound. The amount of binder compound used is typically 3 to 15% by mass based on the amount of glass staple fiber. Examples of materials for the glass staple fiber include E-glass, C-glass, A-glass, S-glass, D-glass, NE-glass, and low-dielectric-constant glass. A thickness of the glass nonwoven fabric is typically 50 μm to 1,000 μm, preferably 100 to 900 μm. Incidentally, the thickness of the glass nonwoven fabric in the present disclosure refers to the value measured in accordance with JIS P8118:1998 using a digital gauge DG-925 (load 110 grams and face diameter 10 mm) manufactured by ONO SOKKI Co., Ltd. In order to enhance the affinity with a fluororesin, the glass nonwoven fabric may be subjected to treatment with a silane coupling agent.

Many glass nonwoven fabrics have an extremely high degree of porosity of 80% or more, so that it is preferable to use one thicker than a sheet composed of a fluororesin and then use it by compression thereof under pressure.

The fabric layer composed of glass fibers may also be a layer stacked with glass cloth and a glass nonwoven fabric. This allows the properties of each material to be combined to provide optimal properties. The fabric layer composed of glass fibers may be in the form of a prepreg impregnated with a resin.

In the laminate, a fabric layer composed of glass fibers and the sheet may be bonded at their interface, or the sheet may be partially or entirely impregnated into the fabric layer composed of glass fibers.

Furthermore, the laminate may be a laminate in which a fabric composed of glass fibers has been impregnated with a fluororesin composition to fabricate a prepreg. The laminate may also be a laminate in which the prepreg thus obtained has been stacked with the fluororesin sheet of the present disclosure. In this case, the fluororesin composition to be used upon fabrication of the prepreg is not limited, and the sheet of the present disclosure may also be used.

A resin film to be used as the substrate layer described above is preferably a heat-resistant resin film or a thermosetting resin film. Examples of the heat-resistant resin film include polyimide, modified polyimide, a liquid crystal polymer, and polyphenylene sulfide. Examples of the thermosetting resin include an epoxy resin, bismaleimide, a polyphenylene oxide, a modified polyphenylene ether, a polyphenylene ether, and polybutadiene.

The heat-resistant resin film and thermosetting resin film may also include a reinforcing fiber. The reinforcing fiber is not limited, and examples thereof include glass cloth in particular a low-dielectric-constant fiber.

The characteristics such as the dielectric properties, coefficient of linear expansion, and water absorption of the heat-resistant resin film and thermosetting resin film are not limited, and for example, the dielectric constant at 20 GHz is preferably 3.8 or less, more preferably 3.4 or less, and still more preferably 3.0 or less. The dielectric loss tangent at 20 GHz is preferably 0.0030 or less, more preferably 0.0025 or less, and still more preferably 0.0020 or less. The coefficient of linear expansion is preferably 100 ppm/° C. or less, more preferably 70 ppm/° C. or less, and still more preferably 40 ppm/° C. or less. The water absorption is preferably 1.0% or less, more preferably 0.5% or less, and still more preferably 0.1% or less.

When the metal-clad laminate including the above-described sheet and copper foil as essential components is stacked with the substrate layer such as the resin film layer, the metal-clad laminate can be stacked by allowing the sheet layer side thereof to be adhered to the substrate layer. In this case, the metal-clad laminate for use may be a metal-clad laminate in which the sheet layer side was surface-treated prior to stacking to improve its adhesive performance. The surface treatment employed here is not limited, and an example thereof includes the aforementioned plasma treatment.

In the above-described laminate, the stacking order of the copper foil layer, the substrate, and the aforementioned sheet and the production method are not limited, and the laminate can be configured of layers depending on its purpose.

Specific examples of the laminate stacked according to the aforementioned stacking order include those configured in orders of the substrate layer/sheet/copper foil layer, the copper foil layer/sheet/substrate layer/sheet/copper foil layer, and the copper foil layer/substrate layer/sheet/substrate layer/copper foil layer.

Also, the laminate may also include another layer, if necessary.

The silica is preferably spherical silica.

The silica preferably has a dielectric loss tangent at 10 GHz of 0.0025 or less.

The inorganic particle is preferably coated with a silane coupling agent.

The content of the inorganic particle is preferably 40% by mass or more of the entire composition.

The inorganic particle has an average particle size of 0.5 μm or more.

The organosiloxane preferably has a viscosity from 3 to 18,000 mm²/s (25° C.).

The content of the organosiloxane is preferably less than 20% by mass of the entire composition.

The organosiloxane is preferably a modified organosiloxane.

The modified organosiloxane preferably has, at any or all of its side chain, one end, and both ends, at least one selected from the group consisting of a hydrogen atom, an amino group, an ether group, an epoxy group, a mercapto group, a carboxyl group, an acrylic group, a methacrylic group, a carboxylic acid anhydride group, an alkyl group, an aralkyl group, a fluoroalkyl group, a perfluoroalkyl group, an ester group, an amide group, and a phenyl group.

The modified polyorganosiloxane preferably has, at any or all of its side chain, one end, and both ends, at least one selected from the group consisting of a hydrogen atom, an amino group, a carboxyl group, an acrylic group, a carboxylic acid anhydride group, an alkyl group, a fluoroalkyl group, a perfluoroalkyl group, an ester group, an amide group, and a phenyl group.

The modified polyorganosiloxane preferably has, at any of its side chain, one end, and both ends, at least one selected from the group consisting of a hydrogen atom, an amino group, a carboxyl group, an acrylic group, a fluoroalkyl group, a phenyl group, and a carboxylic acid anhydride group.

The present disclosure is also a sheet composed of the aforementioned moisture absorption suppressing composition.

The sheet of the present disclosure preferably has an increased value of moisture content of 60 ppm or less when stored for 24 hours in an environment of 30° C. and 90% RH.

The sheet of the present disclosure preferably has an increased rate of dielectric loss tangent of 30% or less when stored for 24 hours in an environment of 30° C. and 90% RH.

The sheet of the present disclosure preferably has a coefficient of linear expansion (CTE) of 200 ppm/K or less.

The present disclosure is also a method for producing the aforementioned sheet, characterized by forming a composition obtained by mixing a fluororesin particle, an inorganic particle, and an organosiloxane.

The method for producing the sheet is preferably a method of forming using a composition substantially composed of a fluororesin particle, an inorganic particle, and an organosiloxane.

The present disclosure is also a metal-clad laminate including a metal layer and the aforementioned sheet as essential layers.

The sheet included in the metal-clad laminate may include at least one selected from the group consisting of formaldehyde, formic acid, hexamethylcyclotrisiloxane, octamethylcyclotetrasiloxane, and decamethylcyclopentasiloxane.

The metal layer is preferably copper foil.

The present disclosure is also a circuit board, characterized by including the aforementioned metal-clad laminate in which the metal layer is copper foil.

### EXAMPLES

The present disclosure will now be described in detail below based on the following Examples. In the following Examples, the terms “parts” and “%” represent “parts by mass” and “% by mass,” respectively, unless otherwise specified.

The spherical silica used in each Example and Comparative Example is as follows:

SC6500-SQ (Silica A: average particle size 2.1 μm, dielectric loss tangent 0.00051), manufactured by Admatechs Co., Ltd.
SC6500-SQ (average particle size 2.1 μm), manufactured by Admatechs Co., Ltd. treated with 3-aminopropyltriethoxysilane in a treated amount of 0.2% by mass based on the mass of silica particles (dielectric loss tangent 0.00058).
SC6500-SQ (average particle size 2.1 μm), manufactured by Admatechs Co., Ltd. treated with 3-aminopropyltriethoxysilane in a treated amount of 1% by mass based on the mass of silica particles (dielectric loss tangent 0.00044).
SC6500-SQ (average particle size 2.1 μm), manufactured by Admatechs Co., Ltd. treated with 3-isocyanatepropyltriethoxysilane in a treated amount of 0.2% by mass based on the mass of the silica particles (dielectric loss tangent 0.00052).

The crushed silica used in each Example and Comparative Example is as follows:

ZA-30 (Silica B: average particle size 5.6 μm, dielectric loss tangent 0.00838), manufactured by Tatsumori Ltd.

The organosiloxanes used in each Example and Comparative Example are as follows:

KF-96-50CS (polydimethylsilicone oil: Abbreviation PDMS), manufactured by Shin-Etsu Chemical Co., Ltd.
X-22-162C (polydimethylsilicone oil with both ends modified with a RCOOH group), manufactured by Shin-Etsu Chemical Co., Ltd.
KF-8012 (polydimethylsilicone oil with both ends modified with a RNH₂ group), manufactured by Shin-Etsu Chemical Co., Ltd.
X-22-168B (polydimethylsilicone oil with both ends modified with a carboxylic acid anhydride group), manufactured by Shin-Etsu Chemical Co., Ltd.
X-22-2445 (polydimethylsilicone oil with both ends modified with an acrylic group), manufactured by Shin-Etsu Chemical Co., Ltd.
KF-868 (polydimethylsilicone oil with a side chain modified with a RNH₂ group), manufactured by Shin-Etsu Chemical Co., Ltd.
KF-99 (polydimethylsilicone oil with its side chain modified with a hydrogen atom), manufactured by Shin-Etsu Chemical Co., Ltd.
KF-50-100CS (polydimethylsilicone oil with its side chain modified with a phenyl group), manufactured by Shin-Etsu Chemical Co., Ltd.
X-22-822 (polydimethylsilicone oil with its side chain modified with a C₂H₄CF₃ group), manufactured by Shin-Etsu Chemical Co., Ltd.

The fluororesin particle (PTFE) used in each Example had the following properties:
Average particle size: 500 μm
Apparent density: 460 g/L
Standard specific gravity: 2.17

### (Powder Rolling Forming)

The fluororesin particles (PTFE), silica, and organosiloxane were weighed out in the proportions shown in Tables 1 and 2 and stirred twice for 30 seconds at 6 increments using a Wonder Crusher at room temperature. The resulting mixture was rolled with two rolls (the roll gap was set to 100 μm and a roll temperature was 100° C.) to obtain a sample with a film thickness of 125 μm, which was then sintered at 360° C. for 15 minutes to obtain a sheet.

### (Paste Extrusion Forming)

The fluororesin particles (PTFE), silica, and organosiloxane were weighed out in predetermined amounts in the proportions shown in Table 1 and mixed in a mixer in the presence of dry ice. The temperature during mixing was −10° C. or lower.

To the resulting mixed powder was added oil (IP Solvent 2028) in a percentage from 18 to 23% with respect to the powder and the mixture was mixed and aged for approximately 5 hours.

The aged composition was preliminarily formed under the conditions of a pressure of 3 MPa, and the preformed article was extruded under the conditions of 40° C. and 50 mm/min to obtain an extruded sample. The extruded sample was rolled with two-roll mills to obtain a sample with a film thickness of 125 μm, which was then dried at 200° C. for 2 hours and sintered at 360° C. for 15 minutes to obtain a sheet.

Each sample obtained was evaluated based on the following criteria.

### [Thickness of Sheet]

The thickness of the sheet was measured using a micrometer.

### [Dielectric Constant (Dk) and Dielectric Loss Tangent (Df) of Sheet]

The relative dielectric constant and dielectric loss tangent at 25° C. and 10 GHz were measured using a split-cylinder dielectric constant/dielectric loss tangent measuring apparatus (manufactured by EM Lab P&K.).

### [Constant Humidity Test]

Each sample was placed in a constant-humidity and temperature chamber maintained at 30° C. and 90% RH, and the change in a dielectric loss tangent after 24 hours was tracked.

The increased rate of the dielectric loss tangent was calculated using the following formula:

Increased rate (%)=(dielectric loss tangent after 24 hours−dielectric loss tangent before constant humidity test)/dielectric loss tangent before constant humidity test×100

### [Coefficient of Linear Expansion (CTE)]

A TMA measurement was performed in tension mode using a TMA-7100 (manufactured by Hitachi High-Tech Science Corporation). A sheet cut to dimensions of 20 mm in length, 5 mm in width, and 150 μm in thickness was used as a sample piece. The distance between chucks was set to 10 mm. A coefficient of linear expansion was determined based on the displacement amount of the sample measured during heating from 0 to 150° C. at a heating rate of 2° C./min while a load of 49 mN was applied.

The results are shown in Table 1 and Table 2.

### [Increased Value of Moisture Content of Sheet]

Each sample was placed in a constant-humidity and temperature chamber maintained at 30° C. and 90% RH and stored for one week. The samples were shredded before and after the constant-humidity test and charged into a vaporization chamber of a moisture measuring apparatus (CA-200, VA-200 manufactured by Mitsubishi Chemical Corporation), and the moisture generated at 250° C. was analyzed.

The moisture content of the sheet of Comparative Example 1 was 190 ppm before the constant-humidity test and 280 ppm after the test.

The moisture content of the sheet of Example 1 was 240 ppm before the constant-humidity test and 220 ppm after the test.

It is to be noted that the significant figures are two digits.

### [Content of Formaldehyde and Other Components in Sheet Included in Metal-Clad Laminate]

The sample was cut into a sample with an approximate 10 mm square, encapsulated in a heating container, and heated at 360° C. for 30 minutes in the presence of a N₂ gas. The gas generated was collected in an adsorption tube and underwent a thermal desorption GC/MS analysis (TD-100 manufactured by MARKS INTERNATIONAL LTD. and GC7890A+5875C, manufactured by Agilent Technologies, Inc.). A calibration curve was created from the absolute amounts of the standard products and the obtained peak area values, and the content was quantitatively determined.

The amount of gas generated in the sheet of Example 5 was 220 μg/g, with a cyclic siloxane being observed.

The amount of gas generated in the sheet of Example 9 was 110 μg/g, with a cyclic siloxane being observed.

### [Water Absorption Test]

The test was conducted in accordance with IPC-TM-650 test method 2.6.2.1. The water absorption was calculated using the following expression:

$$Increase in weight , percent = \frac{wet weight - conditioned weight}{conditioned weight} \times 100 \qquad [ Expression 1 ]$$

The sheet of Example 1 had a water absorption of 0.021 wt %.

The sheet of Comparative Example 1 had a water absorption of 0.195 wt %.

The sheet of Example 5 had a water absorption of 0.022 wt %.

The sheet of Example 6 had a water absorption of 0.018 wt %.

### [Surface Tension for Liquid Repellency Test]

The sheet was immersed in a “wetting tension test mixture” manufactured by Wako Pure Chemical Industries, Ltd. for one minute at room temperature, then washed with distilled water. Whether or not the wetting tension test mixture penetrated the sheet was then visually confirmed. Wetting tension test mixtures No. 22.6 to 70.0 were used, and the critical tension for liquid repellency was determined by the value of the test liquid with the lowest surface tension among the wetting tension test mixtures that did not penetrate the sheet.

The sheet of Example 1 had a critical tension for liquid repellency of 22.6 mN/M.

The sheet of Comparative Example 1 had a critical tension for liquid repellency of 22.6 mN/M.

The sheets of Comparative Example 1 and Example 1 had a similar surface tension for liquid repellency, but the sheet of Comparative Example 1 was unsatisfactory in terms of the water absorption. The composition of the present disclosure can also reduce water absorption.

TABLE 1

| | | | | Amount of | | | |
|---|---|---|---|---|---|---|---|
| | | | | surface | | | |
| | | | | treatment | | | |
| | Amount | | | (% vs | Organosiloxane | | |
| | of silica | | Silica surface | amount of | | Viscosity | Amount |
| | (%) | Silica | treatment | silica) | Product No. | (mm²/s) | added (%) |
| Example 1 | 60 | A | Aminopropyl | 1 | KF-96-50CS | 50 | 0.6 |
| | | | | | (PDMS) | | |
| Example 2 | 60 | A | Aminopropyl | 1 | KF-96-50CS | 50 | 0.2 |
| | | | | | (PDMS) | | |
| Comparative | 60 | A | Aminopropyl | 1 | None | — | — |
| Example 1 | | | | | | | |
| Example 3 | 60 | B | None | 0 | KF-96-50CS | 50 | 0.6 |
| | | | | | (PDMS) | | |
| Comparative | 60 | B | None | 0 | None | — | — |
| Example 2 | | | | | | | |
| Example 4 | 60 | A | None | 0 | KF-96-50CS | 50 | 0.6 |
| | | | | | (PDMS) | | |
| Comparative | 60 | A | None | 0 | None | — | — |
| Example 3 | | | | | | | |
| Example 5 | 60 | A | Aminopropyl | 0.2 | KF-96-50CS | 50 | 0.6 |
| | | | | | (PDMS) | | |
| Example 6 | 60 | A | Isocyanate | 0.2 | X-22-162C | 50 | 0.6 |
| | | | | | (with both | | |
| | | | | | —RCOOH | | |
| | | | | | ends) | | |
| Example 7 | 50 | A | Aminopropyl | 0.2 | X-22-162C | 220 | 0.5 |
| | | | | | (with both | | |
| | | | | | —ROOOH | | |
| | | | | | ends) | | |

| | | Dk | Df | | |
|---|---|---|---|---|---|
| | Production | Initial | Initial | Increased | CTE |
| | method | value | value | rate (%) | (ppm/K) |
| Example 1 | Powder rolling | <3 | 0.00071 | 4.4 | 41 |
| | molding | | | | |
| Example 2 | Paste | <3 | 0.00070 | 2.7 | 43 |
| | extrusion | | | | |
| Comparative | Powder rolling | <3 | 0.00081 | 14 | 41 |
| Example 1 | molding | | | | |
| Example 3 | Powder rolling | <3 | 0.00167 | 2.4 | 64 |
| | molding | | | | |
| Comparative | Powder rolling | <3 | 0.00369 | 21 | 39 |
| Example 2 | molding | | | | |
| Example 4 | Powder rolling | <3 | 0.00064 | 1.8 | 49 |
| | molding | | | | |
| Comparative | Powder rolling | <3 | 0.00042 | 16 | 54 |
| Example 3 | molding | | | | |
| Example 5 | Powder rolling | <3 | 0.00057 | 2.2 | 46 |
| | molding | | | | |
| Example 6 | Powder rolling | <3 | 0.00062 | 5.4 | 46 |
| | molding | | | | |
| Example 7 | Powder rolling | <3 | 0.00066 | 5 | 68 |
| | molding | | | | |

TABLE 2

| | | | | Amount of | | | |
|---|---|---|---|---|---|---|---|
| | | | | surface | | | |
| | Amount | | | treatment | Organosiloxane | | |
| | of silica | | Silica surface | (% vs amount | | Viscosity | Amount |
| | (%) | Silica | treatment | of silica) | Product No. | (mm²/s) | added (%) |
| Example 8 | 60 | A | Aminopropyl | 0.2 | KF-96-200CS | 200 | 0.6 |
| | | | | | (PDMS) | | |
| Example 9 | 60 | A | Aminopropyl | 0.2 | X-22-162C | 220 | 0.6 |
| | | | | | (with both | | |
| | | | | | —RCOOH ends) | | |
| Example 10 | 60 | A | Aminopropyl | 0.2 | KF-96-50CS | 50 | 1.8 |
| | | | | | (PDMS) | | |
| Example 11 | 60 | A | Aminopropyl | 0.2 | KF-96-50CS | 50 | 1.2 |
| | | | | | (PDMS) | | |
| Example 12 | 60 | A | Aminopropyl | 0.2 | KF-8012 | 90 | 0.6 |
| | | | | | (with both | | |
| | | | | | —RNH₂ ends) | | |
| Example 13 | 60 | A | Aminopropyl | 0.2 | X-22-168B | 180 | 0.6 |
| | | | | | (with both acid | | |
| | | | | | anhydride ends) | | |
| Example 14 | 60 | A | Aminopropyl | 0.2 | X-22-2445 | 55 | 0.6 |
| | | | | | (with both | | |
| | | | | | acryli cends | | |
| Example 15 | 60 | A | Aminopropyl | 0.2 | KF-868 | 90 | 0.6 |
| | | | | | (with a —RNH₂ | | |
| | | | | | side chain) | | |
| Example 16 | 60 | A | Aminopropyl | 0.2 | KF-99 | 20 | 0.6 |
| | | | | | (with a —H | | |
| | | | | | side chain) | | |
| Example 17 | 60 | A | Aminopropyl | 0.2 | KF-50-100CS | 100 | 0.6 |
| | | | | | (with a —Ph | | |
| | | | | | side chain) | | |
| Example 18 | 60 | A | Aminopropyl | 0.2 | X-22-822 | 100 | 0.6 |
| | | | | | (with a —C₂H₄CF₃ | | |
| | | | | | side chain) | | |

| | |
|---|---|
| Dk | Df |

| | Production | Initial | Initial | Increased | CTE |
|---|---|---|---|---|---|
| | method | value | value | rate (%) | (ppm/K) |
| Example 8 | Powder rolling | <3 | 0.00063 | 1.8 | 48 |
| | molding | | | | |
| Example 9 | Powder rolling | <3 | 0.00059 | 1.8 | 45 |
| | molding | | | | |
| Example 10 | Powder rolling | <3 | 0.00103 | 0 | 61 |
| | molding | | | | |
| Example 11 | Powder rolling | <3 | 0.00079 | 1.6 | 43 |
| | molding | | | | |
| Example 12 | Powder rolling | <3 | 0.00048 | 3.9 | 47 |
| | molding | | | | |
| Example 13 | Powder rolling | <3 | 0.00061 | 1.7 | 54 |
| | molding | | | | |
| Example 14 | Powder rolling | <3 | 0.00076 | 1.7 | 40 |
| | molding | | | | |
| Example 15 | Powder rolling | <3 | 0.00062 | 1.6 | 45 |
| | molding | | | | |
| Example 16 | Powder rolling | <3 | 0.00048 | 2.6 | 40 |
| | molding | | | | |
| Example 17 | Powder rolling | <3 | 0.0006 | 2.1 | 43 |
| | molding | | | | |
| Example 18 | Powder rolling | <3 | 0.00095 | 0.4 | 41 |
| | molding | | | | |

All the results described above reveal that the sheets of the present disclosure have suppressed water absorption and moisture absorption in highly humid conditions and exhibit excellent performance in terms of suppressed increase in dielectric loss tangent.

### INDUSTRIAL APPLICABILITY

The sheet of the present disclosure can be suitably used for circuit boards, in particular for high-frequency printed circuit boards.

1. A composition comprising a fluororesin, an inorganic particle, and an organosiloxane,
wherein a content of a component other than the fluororesin particle, the inorganic particle and the organosiloxane is 10% by mass or less of the composition.

2. The composition according to claim 1, wherein the inorganic particle is inorganic particle comprising silica as an essential component.

3. The composition according to claim 1, wherein the fluororesin is a perfluorinated fluororesin.

4. The composition according to claim 3, wherein the perfluorinated fluororesin is polytetrafluoroethylene.

5. The composition according to claim 2, wherein the silica is spherical silica.

6. The composition according to claim 2, wherein the silica has a dielectric loss tangent at 10 GHz of 0.0025 or less.

7. The composition according to claim 1, wherein the inorganic particle is coated with a silane coupling agent.

8. The composition according to claim 1, wherein a content of the inorganic particle is 40% by mass or more of an entire composition.

9. The composition according to claim 1, wherein the inorganic particle has an average particle size of 0.5 μm or more.

10. The composition according to claim 1, wherein the organosiloxane has a viscosity from 3 to 18,000 mm²/s (25° C.).

11. The composition according to claim 1, wherein a content of the organosiloxane is less than 20% by mass of the entire composition.

12. The composition according to claim 1, wherein the organosiloxane is a modified organosiloxane.

13. The composition according to claim 12, wherein the modified organosiloxane has, at any or all of its side chain, one end, and both ends, at least one selected from the group consisting of a hydrogen atom, an amino group, an ether group, an epoxy group, a mercapto group, a carboxyl group, an acrylic group, a methacrylic group, a carboxylic acid anhydride group, an alkyl group, an aralkyl group, a fluoroalkyl group, a perfluoroalkyl group, an ester group, an amide group, and a phenyl group.

14. The composition according to claim 12, wherein the modified organosiloxane has, at any or all of its side chain, one end, and both ends, at least one selected from the group consisting of a hydrogen atom, an amino group, a carboxyl group, an acrylic group, a carboxylic acid anhydride group, an alkyl group, a fluoroalkyl group, a perfluoroalkyl group, an ester group, an amide group, and a phenyl group.

15. The composition according to claim 12, wherein the modified organosiloxane has, at any of its side chain, one end, and both ends, at least one selected from the group consisting of a hydrogen atom, an amino group, a carboxyl group, an acrylic group, a fluoroalkyl group, a phenyl group, and a carboxylic acid anhydride group.

16. The composition according to claim 1, wherein
the fluororesin is polytetrafluoroethylene,
the inorganic particle is silica,
a content of the inorganic particle is 50% by mass or more and 70% by mass or less,
the organosiloxane is at least one selected from the group consisting of dimethylpolysiloxane, methylhydrogenpolysiloxane, methylphenylpolysiloxane, a carboxyl-modified polysiloxane, an amino-modified polysiloxane, an acrylic-modified polysiloxane, a carboxylic acid anhydride-modified polysiloxane, and a fluoroalkyl group-modified polysiloxane, and
a content of the organosiloxane is 0.05% by mass or more and 2% by mass or less.

17. A sheet comprising the composition according to claim 1.

18. The sheet according to claim 17, wherein the sheet has an increased value of moisture content of 60 ppm or less when stored for one week in an environment of 30° C. and 90% RH.

19. The sheet according to claim 17, wherein the sheet has an increased rate of dielectric loss tangent of 30% or less when stored for 24 hours in an environment of 30° C. and 90% RH.

20. The sheet according to claim 17, wherein the sheet has a coefficient of linear expansion (CTE) of 200 ppm/K or less.

21. A method for producing the sheet according to claim 17, comprising forming a composition obtained by mixing a fluororesin particle, an inorganic particle, and an organosiloxane.

22. The method for producing the sheet according to claim 21, comprising forming by using a composition substantially composed of fluororesin particle, inorganic particle, and an organosiloxane.

23. A metal-clad laminate comprising a metal layer and the sheet according to claim 17 as essential layers.

24. The metal-clad laminate according to claim 23, wherein the sheet included in the metal-clad laminate comprises at least one selected from the group consisting of formaldehyde, formic acid, hexamethylcyclotrisiloxane, octamethylcyclotetrasiloxane, and decamethylcyclopentasiloxane.

25. The metal-clad laminate according to claim 23, wherein the metal layer is copper foil.

26. A circuit board, comprising the metal-clad laminate according to claim 23.
